(19) United States
(12) Patent Application Publication
(10) Pub. No.: US 2005/0106794 A1
(43) Pub. Date: May 19, 2005

(54) Method of manufacturing a semiconductor device

(75) Inventors: Hitoshi Kuribayashi, Nagano (JP); Reiko Hiruta, Nagano (JP); Ryosuke Shimizu, Nagano (JP)

Correspondence Address: Marc A. Rossi;ROSSI & ASSOCIATES, P.O. Box 826, Ashburn, VA, 20146-0826, US

(73) Assignee: FUJI ELECTRIC HOLDINGS CO., LTD.

(21) Appl. No.: 10/945,556

(22) Filed: Sep. 20, 2004

Related U.S. Application Data
(63) Continuation-in-part of application No. 10/400,171, filed on Mar. 26, 2003.

(30) Foreign Application Priority Data
Feb. 14, 2003 (JP) JP 2003-036685
Mar. 26, 2002 (JP) JP 2002-086122
Oct. 15, 2003 (JP) JP 2003-355629

(51) Int. Cl. H01L 21/336; H01L 21/8234

(52) U.S. Cl. 438/197; 438/308

(57) ABSTRACT

A semiconductor substrate is annealed after forming a trench in a semiconductor substrate and prior to forming a gate insulator film, at an annealing temperature T between 980° C. and 1150° C. in an atmosphere of a gas mixture containing a rare gas and hydrogen, in which the content of hydrogen is 1.3×10⁻¹⁸ exp(0.043T) % or lower in volume, to planarize the side wall of the trench and to round the corners of the trench at the curvature of 0.003 nm⁻¹ or smaller. Alternatively, a semiconductor substrate with a trench formed therein is annealed prior to forming a gate insulator film, at an annealing temperature T between 980° C. and 1040° C. in an atmosphere of a gas mixture containing a rare gas and hydrogen, in which the content of hydrogen is 6.11×10⁻¹⁴ exp(0.0337T) % or higher in volume, to planarize the side wall of the trench but so as not to round the corners of the trench such that the curvature thereof is 0.006 nm⁻¹ or higher. The manufacturing method according to the invention for manufacturing a semiconductor device having an insulated gate structure facilitates planarizing the gate insulator film forming region with fewer manufacturing steps and rounding the trench corners with excellent controllability.

### CROSS REFERENCE TO RELATED APPLICATIONS

This application claims priority from application Serial No. JP 2003-355629, filed on Oct. 15, 2003, and is a continuation-in-part of U.S. appln. Ser. No. 10/400,171, and the entire contents of these documents are incorporated by reference in their entirety.

### BACKGROUND OF THE INVENTION

A. Field of the Invention

The present invention relates to a method of manufacturing a semiconductor device having an insulated gate structure. Specifically, the present invention relates to a technique for planarizing the surface of a region where a gate insulator film is to be formed (hereinafter referred to as a “gate insulator film forming region”) in advance of forming the gate insulator film. The present invention relates also to techniques for forming a trench in a semiconductor substrate, for planarizing the trench side wall of the trench, and for rounding the corners of the trench prior to forming a gate insulator film in the trench.

B. Description of the Related Art

Techniques that utilize a trench formed in a semiconductor substrate for manufacturing a capacitor, for separating device active regions, and for manufacturing an insulated gate field effect transistor (hereinafter referred to as a “trench capacitor technique,” a “trench separation technique,” and a “UMOSFET technique,” respectively) have been used in practice in order to realize higher-density circuit integration in semiconductor devices by improving the packing density of the circuit elements. FIGS. 11 through 17 are cross sectional views, showing successive steps in the conventional method of manufacturing a semiconductor device having a trench filled with a gate insulator film (hereinafter referred to as a “trench MOS semiconductor device”).

As shown in FIGS. 11 through 17, oxide film 2 is first formed on semiconductor substrate 1 (cf. FIG. 11). Then, part of oxide film 2 is removed by a photolithographic technique and by etching to open a region in which a trench is to be formed (hereinafter referred to as a “trench forming region”) (cf. FIG. 12). Trench 3 is formed by anisotropic etching using the remaining oxide film 2 as a mask (cf. FIG. 13). Polymer side wall protective film 4 is on the side wall of the formed trench 3. Polymer film 4 is removed using a hydrofluoric acid etchant (HF etchant). Then, isotropic etching is conducted while oxide film 2 is left unremoved. By the isotropic etching, corners 5a and 5b in the lower part of trench 3 are rounded (cf. FIG. 14).

A thick sacrificial oxide film is formed at a high temperature of 1000° C. or higher, and then the sacrificial oxide film and oxide film 2 remaining on the substrate surface are removed (cf. FIG. 15). By the formation of the sacrificial oxide film at a high temperature and the successive removal thereof together with the remaining oxide film 2, the damage caused by the trench etching is removed and corners 5c and 5d in the upper part of trench 3 are rounded. At the same time, the trench side wall, which will be a gate insulator film forming region, is planarized to some extent. Then, gate insulator film 7 is formed on the substrate surface and in the trench (cf. FIG. 16), and the trench is filled with gate electrode 8 of polysilicon and such an electrode material (cf. FIG. 17). Although not illustrated, a trench MOS semiconductor device is completed by forming a source and such constituent regions.

There exists a conventional technique for rounding the trench corners and for planarizing the trench side wall that anneals the semiconductor substrate with a trench formed therein in a hydrogen atmosphere before forming a gate insulator film. By the hydrogen annealing, the natural oxide film and the chemical oxide film on the gate insulator film forming region in the semiconductor substrate are removed. As the oxide films on the gate insulator film forming region are removed, surface diffusion of the atoms constituting the semiconductor (e.g., silicon atoms) occurs, planarizing the gate insulator film forming region surface. By the surface diffusion, the trench corners are rounded. It has been reported that a radius of curvature of the trench corners that is 6 times or more as long as the gate insulator film thickness, is effective for securing a certain reliability for the gate insulator film (cf. K. Yamabe et al., “Nonplanar Oxidation and Reduction of Oxide Leakage Currents at Silicon Corners by Rounding-off Oxidation”, IEEE Transaction on Electron Devices, (US), 1987, Vol. ED-34, No. 8, pp.1681-1687).

However, the isotropic etching in the conventional manufacturing method fails to sufficiently round corners 5c and 5d in the upper part of the trench, since the isotropic etching is conducted when the substrate surface is covered with an oxide film. Corners 5a and 5b in the lower part of the trench are rounded by isotropic etching, and corners 5c and 5d in the upper part of the trench are rounded by forming a thick sacrificial oxide film and by removing the thick sacrificial oxide film, leading to many manufacturing steps.

The isotropic etching conducted after removing the side wall protective film in the conventional manufacturing method widens the trench width. The variation caused in the setback length of the oxide film mask during removing the side wall protective film causes further variation in the trench width. As a result, variation is caused in the trench opening width which adversely affects the accuracy of positioning the masks in the subsequent steps. The reduced mask positioning accuracy is detrimental to obtaining a finer structure.

Since sufficient flatness is not obtained for the trench side wall, the gate leakage current is higher than that in the semiconductor device having a planar structure. In addition, the gate breakdown voltage is not high enough. Since it is hard for the conventional hydrogen annealing technique to control the surface diffusion of the atoms constituting the semiconductor, variations are caused in the rounding shape of the trench corners in a wafer and/or between wafers.

In view of the foregoing, it would be desirable to obviate the problems described above. It would be also desirable to provide a method of manufacturing a semiconductor device that facilitates, with a few steps, planarizing the surface of the gate insulator film forming region and rounding the trench corners with excellent controllability. The present invention is directed to overcoming or at least reducing the effects of one or more of the problems set forth above.

### SUMMARY OF THE INVENTION

According to a first aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor at an annealing temperature T between 980° C. and 1150° C. in an atmosphere of a gas mixture containing hydrogen in an amount of 1.3×10⁻¹⁸ exp(0.043T) % or lower in volume and a rare gas, to planarize the surface of a gate insulator film forming region of the semiconductor where the gate insulator film is to be formed, and to round the convex corners or the concave corners in the surface of the semiconductor prior to forming the gate insulator film in the gate insulator film forming region.

According to a second aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor at an annealing temperature T between 980° C. and 1150° C. in a hydrogen gas atmosphere, the pressure of which is 1.0×10⁻¹⁷ exp(0.043T) Torr or lower, to planarize the surface of a gate insulator film forming region of the semiconductor where the gate insulator film is to be formed and to round the convex corners or the concave corners in the surface of the semiconductor prior to forming the gate insulator film in the gate insulator film forming region.

According to a third aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor in an atmosphere of a gas mixture containing hydrogen, the content R thereof is higher than 0% and lower than 100% in volume, and a rare gas at a temperature of 231n(R/1.3×10⁻¹⁸) ° C. or higher, to planarize the surface of a gate insulator film forming region of the semiconductor where the gate insulator film is to be formed and to round the convex corners or the concave corners in the surface of the semiconductor prior to forming the gate insulator film in the gate insulator film forming region.

According to a fourth aspect of the invention, there is provided a method of manufacturing a semiconductor device having an insulated gate structure. The insulated gate structure including a gate insulator film between a semiconductor and a gate electrode. The gate insulator film is in contact with the semiconductor. The method includes a step of annealing the semiconductor in a hydrogen gas atmosphere, the pressure P of which is between 0 Torr and 760 Torr, at an annealing temperature of 231n(P/1.0×10⁻¹⁷) ° C. or higher, to planarize the surface of a gate insulator film forming region of the semiconductor where the gate insulator film is to be formed and to round the convex corners or the concave corners in the surface of the semiconductor prior to forming the gate insulator film in the gate insulator film forming region.

According to the first through fourth aspects of the invention, the semiconductor surface in the gate insulator film forming region is planarized at the atomic level by the migration of the atoms constituting the semiconductor during the annealing and the convex corners or the concave corners in the surface of the semiconductor are rounded with a curvature of 0.003 nm⁻¹ or smaller such that radius of curvature of the corners is 6 times or more as long as the thickness of the gate insulator film.

According to a fifth aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor at an annealing temperature T between 980° C. and 1040° C. in an atmosphere of a gas mixture containing hydrogen in an amount of 6.11×10⁻¹⁴ exp(0.0337T) % or higher in volume and a rare gas, to planarize the surface of a gate insulator film forming region of the semiconductor where the gate insulator film is to be formed prior to forming the gate insulator film in the gate insulator film forming region.

According to a sixth aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor at an annealing temperature T between 980° C. and 1040° C. in a hydrogen gas atmosphere, the pressure of which is 4.64×10⁻¹³ exp(0.0337T) Torr or higher, to planarize the surface of a gate insulator film forming region of the semiconductor where the gate insulator film is to be formed prior to forming the gate insulator film in the gate insulator film forming region.

According to a seventh aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor in an atmosphere of a gas mixture containing hydrogen, the content R thereof being between 30% and 100% in volume, and a rare gas at a temperature of 29.71n(R/6.11×10⁻¹⁴) ° C. or lower, to planarize the surface of a gate insulator film forming region of the semiconductor where the gate insulator film is to be formed prior to forming the gate insulator film in the gate insulator film forming region.

According to an eighth aspect of the invention, there is provided a method of manufacturing a semiconductor device having an insulated gate structure. The insulated gate structure includes a gate insulator film between a semiconductor and a gate electrode. The gate insulator film is in contact with the semiconductor. The method includes a step of annealing the semiconductor in a hydrogen gas atmosphere, the pressure P thereof being between 228 Torr and 760 Torr, at an annealing temperature of 29.71n(P/4.64×10⁻¹³) ° C. or lower, to planarize the surface of a gate insulator film forming region of the semiconductor where the gate insulator film is to be formed prior to forming the gate insulator film in the gate insulator film forming region.

According to the fifth through eighth aspects of the invention, the convex corners or the concave corners in the surface of the semiconductor are not rounded, since the curvature of the convex corners or the concave corners becomes 0.006 nm⁻¹ or higher. However, the semiconductor surface in the gate insulator film forming region is planarized at the atomic level by the migration of the atoms constituting the semiconductor during the annealing.

Advantageously, the total amount of the impurity gas components in the atmosphere of the gas mixture other than the hydrogen gas component and the rare gas component is about 50 ppb or less. Preferably the total amount of the impurity gas components in the hydrogen gas atmosphere other than the hydrogen gas component is about 50 ppb or less.

As long as the total amount of the impurity gas components in a hydrogen gas atmosphere or in the atmosphere of a gas mixture is about 50 ppb or less, the semiconductor surface is not roughened by annealing. Since the surface diffusion of the atoms constituting the semiconductor is controlled with excellent controllability, the throughput of the semiconductor device is improved. In contrast, when the total amount of oxygen, nitrogen, moisture and such impurity gas components exceeds about 50 ppb to the higher side, the semiconductor surface is roughened, the surface diffusion controllability of the atoms constituting the semiconductor is impaired, the round shape of the corners is not reproduced well, and the throughput of the semiconductor device is lowered.

Advantageously, the step of annealing is conducted at a pressure between about 10 Torr and 760 Torr. Since an annealing apparatus having a simple structure can be used, mass-production is facilitated. Annealing under a pressure of lower than about 10 Torr, which requires the annealing apparatus having a complicated structure, is not suited for mass-production of semiconductor devices.

Advantageously, the step of annealing is conducted at the ordinary pressure. The annealing under the ordinary pressure, which can be conducted in the apparatus having a further simplified structure with excellent controllability, is suited for mass-production.

According to the invention, the surface of the gate insulator film forming region is planarized at the atomic level. In the semiconductor devices including a gate insulator film in the trench, the trench side wall, which is a gate insulator film forming region, is planarized at the atomic level and the trench corners are rounded with excellent controllability through a few steps. Therefore, very reliable semiconductor devices are obtained with low manufacturing costs and with excellent throughput.

### BRIEF DESCRIPTION OF THE DRAWINGS

The foregoing advantages and features of the invention will become apparent upon reference to the following detailed description and the accompanying drawings, of which:

FIG. 1 is a cross sectional view showing an arrangement in a step for manufacturing a trench MOS semiconductor device according to an embodiment of the invention.

FIG. 2 is a cross sectional view showing the arrangement in the step subsequent to the step of FIG. 1 for manufacturing the trench MOS semiconductor device according to the embodiment of the invention.

FIG. 3 is a cross sectional view showing the arrangement in the step subsequent to the step of FIG. 2 for manufacturing the trench MOS semiconductor device according to the embodiment of the invention.

FIG. 4 is a cross sectional view showing the arrangement in the step subsequent to the step of FIG. 3 for manufacturing the trench MOS semiconductor device according to the embodiment of the invention.

FIG. 5 is a cross sectional view showing the arrangement in the step subsequent to the step of FIG. 4 for manufacturing the trench MOS semiconductor device according to the embodiment of the invention.

FIG. 6 is a cross sectional view showing the arrangement in the step subsequent to the step of FIG. 5 for manufacturing the trench MOS semiconductor device according to the embodiment of the invention.

FIG. 7 is a set of curves relating the hydrogen content and the annealing temperature with each other with the curvature of the trench corner as a parameter.

FIG. 8 is a set of curves relating the hydrogen gas pressure and the annealing temperature with each other with the curvature of the trench corner as a parameter.

FIG. 9 is an electron micrograph showing the cross section of the trench annealed under the conditions for rounding the trench corners.

FIG. 10 is an electron micrograph showing the cross section of the trench annealed under the conditions under which the trench corners are not rounded.

FIG. 11 is a cross sectional view showing an arrangement in a step in the conventional method of manufacturing a semiconductor device having a trench filled with a gate insulator film.

FIG. 12 is a cross sectional view showing the arrangement in the step subsequent to the step of FIG. 11 in the conventional method of manufacturing the trench MOS semiconductor device.

FIG. 13 is a cross sectional view showing the arrangement in the step subsequent to the step of FIG. 12 in the conventional method of manufacturing the trench MOS semiconductor device.

FIG. 14 is a cross sectional view showing the arrangement in the step subsequent to the step of FIG. 13 in the conventional method of manufacturing the trench MOS semiconductor device.

FIG. 15 is a cross sectional view showing the arrangement in the step subsequent to the step of FIG. 14 in the conventional method of manufacturing the trench MOS semiconductor device.

FIG. 16 is a cross sectional view showing the arrangement in the step subsequent to the step of FIG. 15 in the conventional method of manufacturing the trench MOS semiconductor device.

FIG. 17 is a cross sectional view showing the arrangement in the step subsequent to the step of FIG. 16 in the conventional method of manufacturing the trench MOS semiconductor device.

### DETAILED DESCRIPTION OF SPECIFIC EMBODIMENTS

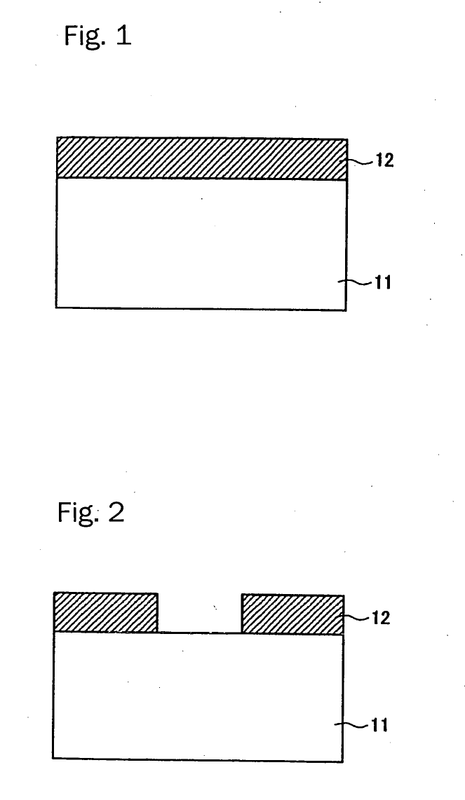

Now the invention will be described in detail hereinafter with reference to the accompanying drawing figures which illustrate the preferred embodiments of the invention. FIGS. 1 through 6 are cross sectional views showing the arrangements in the successive steps for manufacturing a trench MOS semiconductor device according to an embodiment of the invention.

A well region (not shown) and such regions are formed in the surface portion of a silicon semiconductor substrate 11 through a conventional process for forming the ordinary MOS semiconductor device. Oxide film 12 is formed on semiconductor substrate 11 (cf. FIG. 1). A mask of photoresist having a pattern for opening a trench forming region is formed on oxide film 12. A mask having a predetermined trench pattern is formed by etching oxide film 12 using the mask formed as described above (cf. FIG. 2).

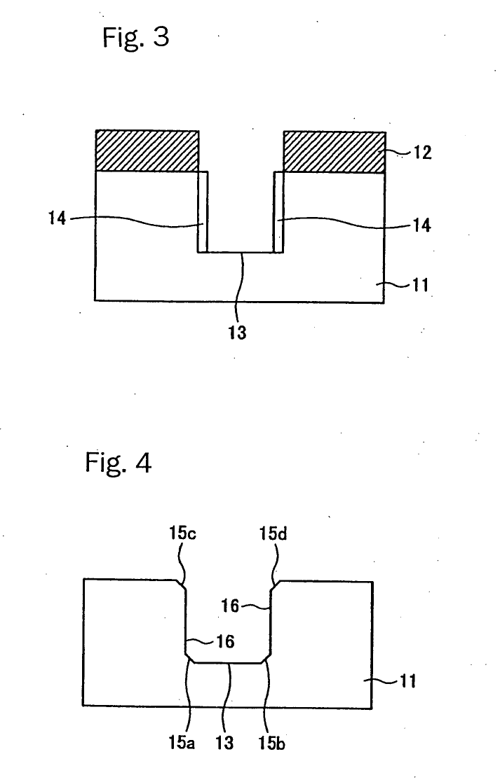

Trench 13 is formed by etching semiconductor substrate 11 by reactive ion etching as an anisotropic etching using the remaining oxide film 12 as a mask. In this trench etching, polymer side wall protective film 14 is formed on the side wall of trench 13 (cf. FIG. 3). Polymer film 14 and oxide film 12 used for a mask are removed by a hydrofluoric acid (HF) etchant, Then the trench side wall is cleaned by the ordinary RCA cleaning method.

Semiconductor substrate 11 is loaded into a heat treatment furnace and annealed under first annealing conditions described later. The natural oxide film on the substrate and the chemical oxide film formed during the RCA cleaning are removed by the annealing treatment. Semiconductor substrate 11 is kept in the heat treatment furnace and the annealing conditions are changed to the second annealing conditions described later. Then, the trench side wall and a region which will be gate insulator film forming region 16 are planarized by the heat treatment conducted under the second annealing conditions. At the same time, trench corners 15a and 15b in the lower part of trench 13, which are concave corners in the semiconductor surface, and trench corners 15c and 15d in the upper part of trench 13, which are convex corners in the semiconductor surface, are rounded by the heat treatment conducted under the second annealing conditions (cf. FIG. 4).

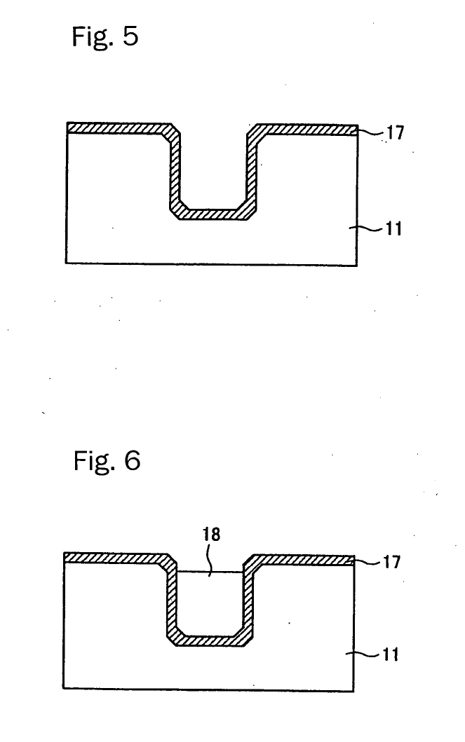

Gate insulator film 17 is formed on the substrate surface and in the trench (cf. FIG. 5), and then the trench is filled with polysilicon. The polysilicon in the trench is etched back, resulting in gate electrode 18 (cf. FIG. 6). Although not illustrated, a source region and a drain region subsequently are formed and an interlayer insulator film is deposited. Finally, a trench MOS semiconductor device is completed by forming wiring on the interlayer insulator film and by covering the semiconductor substrate with interlayer insulator film and the wiring formed thereon with a passivation film.

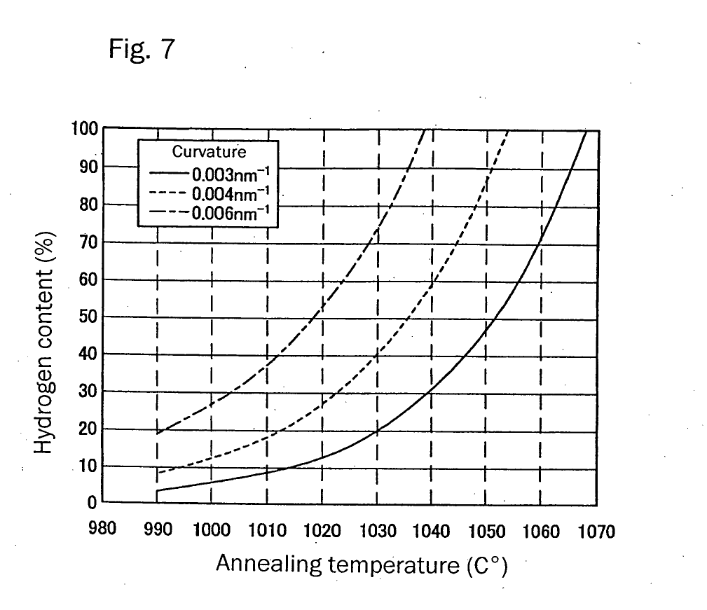

Now the first annealing conditions and the second annealing conditions will be described in detail below. To obtain the first and second annealing conditions, semiconductor substrates with a trench formed therein are positioned in a heat treatment furnace and treated thermally under ordinary pressure in atmospheres of gas mixtures containing varying amounts of hydrogen and a rare gas such as argon for 3 minutes. The relationships between the hydrogen content, the annealing temperature, and the curvature of the trench corner are investigated. The results are shown in FIG. 7.

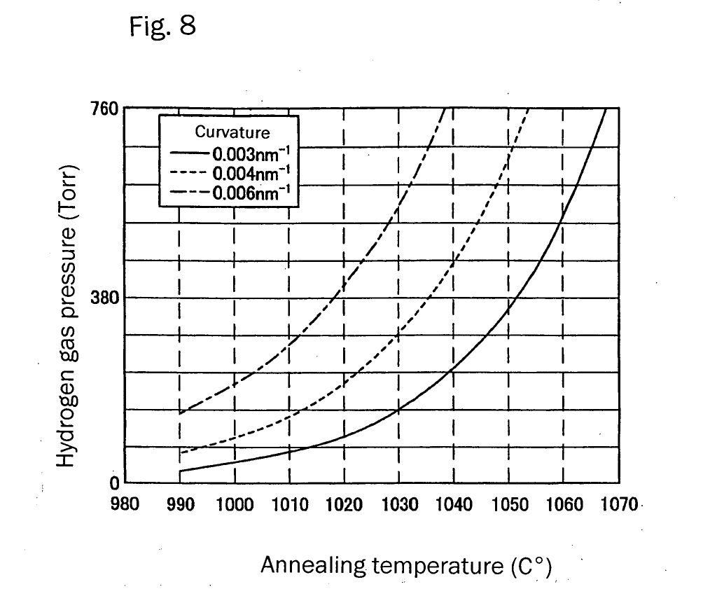

The first and second annealing conditions for annealing in the atmosphere of 100% hydrogen are also obtained. To obtain the first and second annealing conditions for the atmosphere of 100% hydrogen, semiconductor substrates with a trench formed therein are positioned in a heat treatment furnace and treated thermally in the atmosphere of 100% hydrogen gas for 3 minutes at various pressures. The relationships between the pressure of 100% hydrogen, the annealing temperature, and the curvature of the trench corner are investigated. The results are shown in FIG. 8.

As FIGS. 7 and 8 clearly indicate, almost the same results are obtained by lowering the hydrogen partial pressure while keeping the total pressure of the gas mixture containing a rare gas such as argon at ordinary pressure (FIG. 7) and by lowering the pressure of 100% hydrogen (FIG. 8). Analyzing the results shown in FIGS. 7 and 8 reveals that when the curvature of the corner is 0.003 nm⁻¹ or lower, it is rounded, and when the curvature of the corner is 0.006 nm⁻¹ or higher, it is not rounded.

Therefore, the trench corners are rounded on the curve in FIG. 7 or 8 representing the curvature of 0.003 nm⁻¹ (solid curve) and in the high temperature range or the low hydrogen partial pressure range (low pressure range) on the right hand side of the solid curve. On the other hand, the trench corners are not rounded on the curve in FIG. 7 or 8 representing the curvature of 0.006 nm⁻¹ (single-dotted chain curve) and in the low temperature range or the high hydrogen partial pressure range (high pressure range) on the left hand side of the single-dotted chain curve.

The approximation of the solid curve representing the curvature of 0.003 nm⁻¹ in FIG. 7 for the atmosphere of a gas mixture is expressed by the following approximate expression (1) using the annealing temperature T expressed in ° C. as a variable. The approximation of the same solid curve is expressed by the following approximate expression (2) using the hydrogen content R expressed in volume % as a variable.
1.3×10⁻¹⁸ exp(0.043T) (1)
231n(R/1.3×10⁻¹⁸) (2)

The approximation of the single-dotted chain curve representing the curvature of 0.006 nm⁻¹ in FIG. 7 for the atmosphere of a gas mixture is expressed by the following approximate expression (3) using the annealing temperature T expressed in ° C. as a variable. The approximation of the same single-dotted chain curve is expressed by the following approximate expression (4) using the hydrogen content R expressed in volume % as a variable.
6.11×10⁻¹⁴ exp(0.0337T) (3)
29.71n(R/6.11×10⁻¹⁴) (4)

The approximation of the solid curve representing the curvature of 0.003 nm⁻¹ in FIG. 8 for the atmosphere of 100% hydrogen is expressed by the following approximate expression (5) using the annealing temperature T expressed in ° C. as a variable. The approximation of the same solid curve is expressed by the following approximate expression (6) using the hydrogen pressure P expressed in Torr as a variable.
1.0×10⁻¹⁷ exp(0.043T) (5)
231n(P/1.0×10⁻¹⁷) (6)

The approximation of the single-dotted chain curve representing the curvature of 0.006 nm⁻¹ in FIG. 8 for the atmosphere of 100% hydrogen is expressed by the following approximate expression (7) using the annealing temperature T expressed in ° C. as a variable. The approximation of the same single-dotted chain curve is expressed by the following approximate expression (4) using the hydrogen pressure P expressed in Torr as a variable.
4.64×10⁻¹³ exp(0.0337T) (7)
29.71n(P/4.64×10⁻¹³) (8)

Based on the knowledge described above, the first annealing conditions are determined as described below. The first annealing conditions are the conditions which facilitate planarizing the semiconductor surface without rounding the trench corners. When the annealing atmosphere is an atmosphere of a gas mixture of hydrogen and a rare gas such as argon, the annealing temperature is between 980° C. and 1040° C. The hydrogen content in the atmosphere of a gas mixture is set preferably at 6.11×10⁻¹⁴ exp(0.0337T) % or higher in volume, wherein T represents the annealing temperature in ° C. Or, the annealing temperature is set preferably at 29.71n(R/6.11×10⁻¹⁴) ° C. or lower, when the hydrogen content R is 30% or higher and lower than 100%.

When the annealing atmosphere is 100% hydrogen, the annealing temperature is between 980° C. and 1040° C. The pressure of 100% hydrogen (the pressure in the firnace) is set preferably at 4.64×10⁻¹³ exp(0.0337T) Torr or higher. Alternatively, when the pressure P of 100% hydrogen (the pressure in the furnace) is between 228 Torr and 760 Torr, the annealing temperature is set preferably at 29.71n(P/4.64×10⁻¹³) ° C. or lower.

The second annealing conditions are the conditions which facilitate rounding the trench corners and planarizing the semiconductor surface. When the treating atmosphere is an atmosphere of a gas mixture of hydrogen and a rare gas such as argon, the annealing temperature is between 980° C. and 1150° C. The hydrogen content in the atmosphere of a gas mixture is set preferably at 1.3×10⁻¹⁸ exp(0.043T) % or lower in volume, wherein T represents the annealing temperature. Or, the annealing temperature is set preferably at 231n(R/1.3×10⁻¹⁸) ° C. or higher, when the hydrogen content R is higher than 0% and lower than 100% in volume.

When the treating atmosphere is 100% hydrogen, the annealing temperature is between 980° C. and 1150° C. The pressure of 100% hydrogen (the pressure in the furnace) is set preferably at 1.0×10⁻¹⁷ exp(0.043T) Torr or lower. Or, when the pressure P of 100% hydrogen (the pressure in the furnace) is higher than 0 Torr and 760 Torr or lower, the annealing temperature is set preferably at 231n(P/1.0×10⁻¹⁷) ° C. or higher.

Under the first and second annealing conditions, it is appropriate for the annealing time to be 10 seconds or longer and 10 minutes or shorter. When the annealing is conducted for 10 seconds or longer, excellent controllability is obtained. For example, the trench corners are shaped with excellent reproducibility. The furnace that thermally treats wafers one by one is not suited for mass-production, when the annealing time exceeds 10 minutes to the longer side. For making the surface diffusion of silicon atoms occur efficiently to further make deformation such as rounding of the trench corners occur, a longer annealing time is more preferable.

Under the first and second annealing conditions, it is preferable for the total amount of impurity gases such as oxygen, nitrogen, and moisture in the annealing atmosphere to be 50 ppb or smaller. Since the silicon surface is prevented from being roughened when the total amount of impurity gases is 50 ppb or smaller, the throughput of the anneal treatment is improved. Under the first and second annealing conditions, the pressure inside the furnace may be reduced when the annealing is conducted in the atmosphere of a gas mixture.

Irrespective of whether the annealing is conducted in the atmosphere of a gas mixture or in the atmosphere of 100% hydrogen, it is appropriate to set the pressure inside the furnace at about 10 Torr or higher from the structural viewpoint of the apparatus. For setting the pressure inside the furnace to be lower than about 10 Torr, it becomes necessary to use a heat treatment furnace having a complicated structure, not suited for mass-production. The investigations conducted by the present inventors have not found any remarkable difference in the ease of surface diffusion between the pressure in the furnace of about 10 Torr and the pressure in the furnace of lower than about 10 Torr.

Trench 13 is formed in silicon semiconductor substrate 11, polymer 14 on the trench side wall is removed, silicon substrate 11 is cleaned by the RCA cleaning method, and the cleaned silicon substrate 11 is annealed in a heat treatment furnace. In the annealing, the pressure in the furnace is set at first at 760 Torr with 100% hydrogen and the silicon substrate 11 is annealed at 1050° C. for 10 seconds. Then, the atmosphere in the furnace is changed to a gas mixture containing 30 volume % of hydrogen and a rare gas while the pressure in the furnace is kept at 760 Torr and silicon substrate 11 is annealed at 1050° C. for 180 seconds.

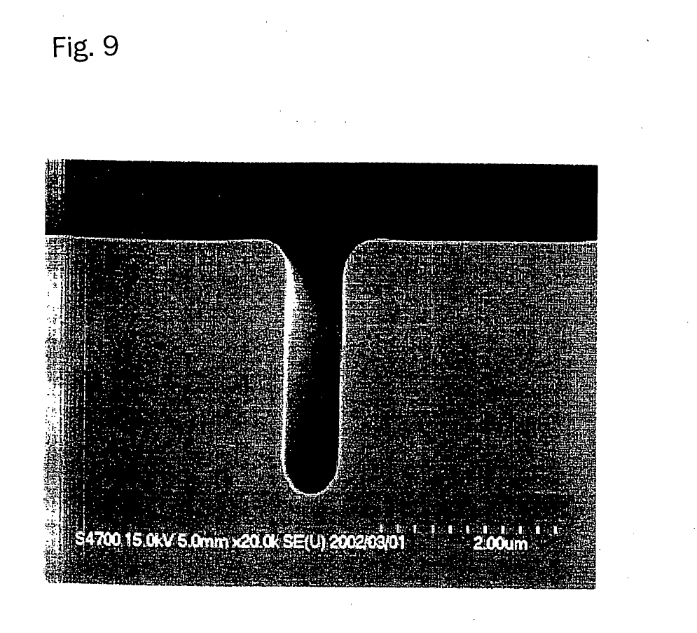

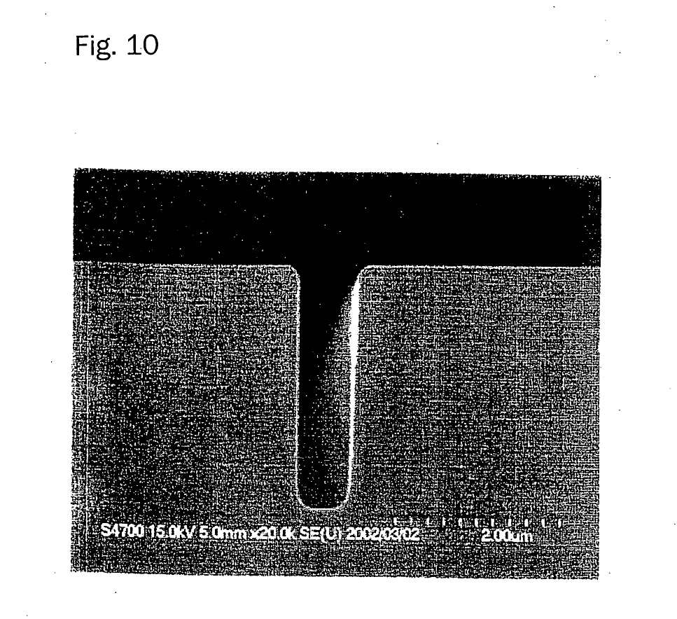

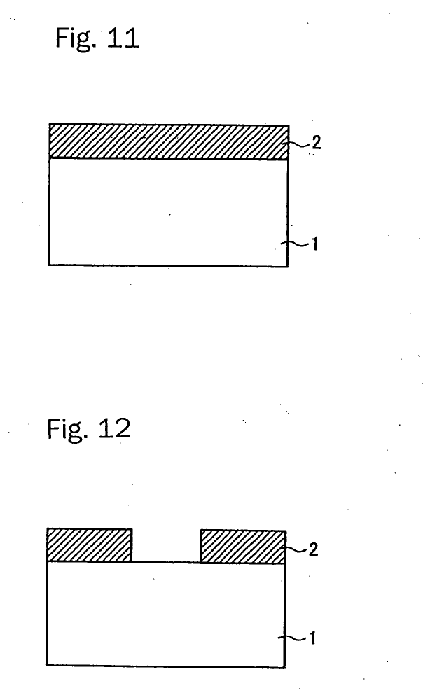

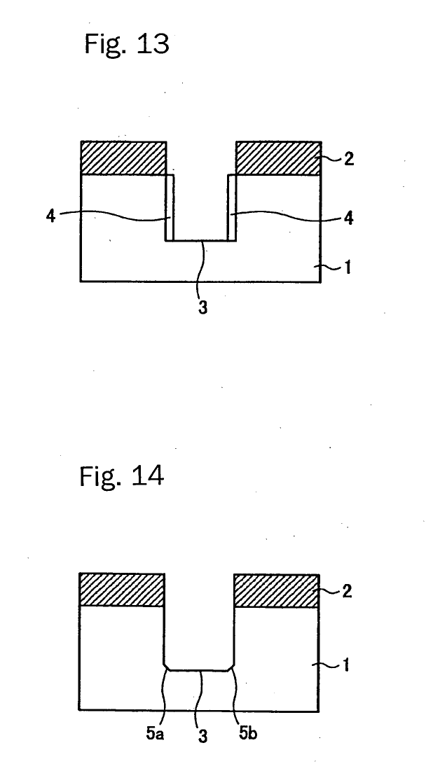

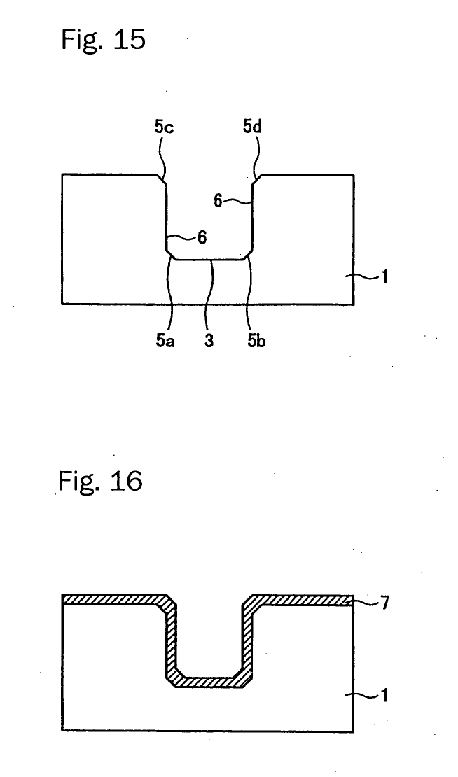

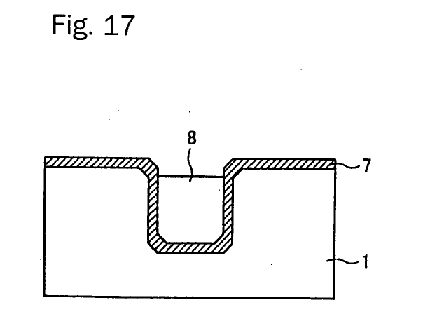

It has been confirmed that the trench corners are rounded with excellent controllability and reproducibility, since it is possible to make the deformation due to the surface diffusion of the silicon atoms occur efficiently by changing the hydrogen content continuously once a clean silicon surface has been exposed as a result of removal of the natural oxide film and the chemical oxide film from the silicon surface. FIG. 9 is an electron micrograph showing the cross section of the trench annealed under the conditions for rounding the trench corners (the second annealing conditions). FIG. 10 is an electron micrograph showing the cross section of the trench annealed under the conditions where the trench corners are not rounded (the first annealing conditions).

As explained above, the trench side wall surface, which will be a gate insulator film forming region, is planarized at the atomic level and the trench corners are rounded with excellent controllability according to the embodiments of the invention. As a result, the gate leakage current is reduced, the variation of the gate breakdown voltage is suppressed, and the gate breakdown voltage is improved. Therefore, a very reliable semiconductor device is obtained with low manufacturing costs and with excellent throughput.

While the invention has been particularly shown and described with reference to the preferred embodiments thereof, it will be understood by those skilled in the art that the foregoing and other changes in form and details can be made therein without departing from the spirit and scope of the invention. For example, the natural oxide film formed on the substrate surface and the chemical oxide film formed during RCA cleaning may be removed with hydrofluoric acid in advance to the annealing treatment and the semiconductor surface may be terminated by hydrogen with no problem. The semiconductor material is not limited to silicon.

The invention is applicable also to planarizing the gate insulator film forming region in the planar-type semiconductor device. Recently, the structures of the planar-type semiconductor devices have become finer and finer. In association with this, the demands for the flatness of the gate insulator film forming region have become more and more severe. By applying the present invention to planarizing the gate insulator film forming region, the gate breakdown voltage and the driving capability are improved. The properties such as Qbd, which is the reliability index of the gate insulator film, are improved by manufacturing the planar MOS semiconductor device by the manufacturing method according to the invention.

The manufacturing method according to the invention is useful for manufacturing semiconductor devices having an insulated gate structure. The manufacturing method according to the invention is especially suited for manufacturing power semiconductor devices that control a high current at a relatively high voltage, such as power MOSFETs and insulated gate bipolar transistors (IGBTs).

Thus, an improved method of manufacturing a semiconductor device having an insulated gate structure has been described according to the present invention. Many modifications and variations may be made to the techniques and structures described and illustrated herein without departing from the spirit and scope of the invention. Accordingly, it should be understood that the methods described herein are illustrative only and are not limiting upon the scope of the invention.

1. A method of manufacturing a semiconductor device including an insulated gate structure that has a gate insulator film between a semiconductor and a gate electrode and in contact with the semiconductor, the method comprising annealing the semiconductor in a gas mixture comprising a rare gas and hydrogen to planarize the surface of a gate insulator film forming region of the semiconductor where a gate insulator film is to be formed and to round convex corners or concave corners in a surface of the semiconductor prior to forming the gate insulator film in the gate insulator film forming region, wherein said annealing conditions are selected from the group consisting of:
(i) an annealing temperature T between about 980° C. and 1150° C. and a content of hydrogen in said gas mixture of about 1.3×10⁻¹⁸ exp(0.043T) % or lower in volume,
(ii) an annealing temperature of about 231n(R/1.3×10⁻¹⁸) ° C. or higher and a content R of hydrogen in said gas mixture that is higher than 0% and lower than 100% in volume,
(iii) an annealing temperature of about 231n(R/1.3×10⁻¹⁸) ° C. or higher and a content R of hydrogen in said gas mixture that is higher than 0% and lower than 100% in volume, and
(iv) an annealing temperature of about 29.71n(R/6.11×10⁻¹⁴) ° C. or lower and a content R of hydrogen in said gas mixture that is in the range of about 30 to 100% in volume.

2. A method as claimed in claim 1, wherein annealing is performed at an annealing temperature T between about 980° C. and 1150° C. and a content of hydrogen in said gas mixture of about 1.3×10⁻¹⁸ exp(0.043T) % or lower in volume.

3. A method as claimed in claim 1, wherein annealing is performed at an annealing temperature of about 231n(R/1.3×10⁻¹⁸) ° C. or higher and a content R of hydrogen in said gas mixture that is higher than 0% and lower than 100% in volume.

4. A method as claimed in claim 1, wherein annealing is performed at an annealing temperature of about 231n(R/1.3×10⁻¹⁸) ° C. or higher and a content R of hydrogen in said gas mixture that is higher than 0% and lower than 100% in volume.

5. A method as claimed in claim 1, wherein annealing is performed at an annealing temperature of about 29.71n(R/6.11×10⁻¹⁴) ° C. or lower and a content R of hydrogen in said gas mixture that is in the range of about 30 to 100% in volume.

6. A method of manufacturing a semiconductor device including an insulated gate structure that has a gate insulator film between a semiconductor and a gate electrode and in contact with the semiconductor, the method comprising annealing the semiconductor in a hydrogen gas atmosphere to planarize the surface of a gate insulator film forming region of the semiconductor where a gate insulator film is to be formed and to round convex corners or concave corners in a surface of the semiconductor prior to forming the gate insulator film in the gate insulator film forming region, wherein said annealing conditions are selected from the group consisting of:
(i) an annealing temperature T between about 980° C. and 1150° C. in a hydrogen gas atmosphere at a pressure of about 1.0×10⁻¹⁷ exp(0.043T) Torr or lower,
(ii) an annealing temperature of about 231n(P/1.0×10⁻¹⁷) ° C. or higher and an annealing pressure P in a range of about 0 to 760 Torr,
(iii) an annealing temperature T between about 980° C. and 1040° C. and an annealing pressure of about 4.64×10⁻¹³ exp(0.0337T) Torr or higher, and
(iv) an annealing temperature of about 29.71n(P/4.64×10⁻¹³) ° C. or lower and an annealing pressure P in the range of about 228 to 760 Torr.

7. A method as claimed in claim 6, wherein annealing is performed at an annealing temperature T between about 980° C. and 1150° C. in a hydrogen gas atmosphere at a pressure of about 1.0×10⁻¹⁷ exp(0.043T) Torr or lower.

8. A method as claimed in claim 6, wherein annealing is performed at an annealing temperature of about 231n(P/1.0×10⁻¹⁷) ° C. or higher and an annealing pressure P in a range of about 0 to 760 Torr.

9. A method as claimed in claim 6, wherein annealing is performed at an annealing temperature T between about 980° C. and 1040° C. and an annealing pressure of about 4.64×10⁻¹³ exp(0.0337T) Torr or higher.

10. A method as claimed in claim 6, wherein annealing is performed at an annealing temperature of about 29.71n(P/4.64×10⁻¹³) ° C. or lower and an annealing pressure P in the range of about 228 to 760 Torr.

11. The method of manufacturing a semiconductor device as claimed in claim 1, wherein the total amount of the impurity gas components in the atmosphere of the gas mixture other than the hydrogen gas component and the rare gas component is about 50 ppb or less.

12. The method of manufacturing a semiconductor device as claimed in claim 6, wherein the total amount of the impurity gas components in the hydrogen gas atmosphere other than the hydrogen gas component is about 50 ppb or less.

13. The method of manufacturing a semiconductor device as claimed in claim 1, wherein the step of annealing is conducted at a pressure in the range of about 10 to 760 Torr.

14. The method of manufacturing a semiconductor device as claimed in claim 6, wherein the step of annealing is conducted at a pressure in the range of about 10 to 760 Torr.

15. The method of manufacturing a semiconductor device as claimed in claim 1, wherein the step of annealing is conducted at ordinary pressure.
